(19) United States
(12) Patent Application Publication
(10) Pub. No.: US 2009/0134865 A1
(43) Pub. Date: May 28, 2009

(54) Position sensor and method for operating a position sensor

(75) Inventors: Karsten Awizio, Wiesbaden (DE); Jurgen Bethke, Regensburg (DE)

Correspondence Address: COHEN, PONTANI, LIEBERMAN & PAVANE LLP, 551 FIFTH AVENUE, SUITE 1210, NEW YORK, NY, 10176, US

(73) Assignee: VDO Automotive AG, Regensburg (DE)

(21) Appl. No.: 11/991,221

(22) PCT Filed: Aug. 21, 2006
(86) PCT No.: PCT/EP2006/065507

§ 371 Date: Mar. 17, 2008

(30) Foreign Application Priority Data
Aug. 31, 2005 (DE) 102005041324.2

(51) Int. Cl. G01B 7/14; G01R 33/07

(52) U.S. Cl. 324/207.2

(57) ABSTRACT

The invention relates to a position sensor and to a method for operating a position sensor. In a position sensor, in particular, a selection area sensor in an automatic gearbox of a motor vehicle, wherein a displaceable slot is in magnetic contact in a contactless manner with a line of Hall elements, whereby the slot is arranged in the direction of displacement of each Hall sensor and comprises a strip made of bit-coded permanent magnets, an evaluation system is connected to the Hall elements which are used to transfer measuring signals of each Hall element. The evaluation system is embodied such that it can determine the actual position of the slot based on measuring signals of each of the Hall elements. The aim of the invention is to improve the connection between the position sensor and a respective evaluation system. As a result, the signal outputs of the two Hall elements are combined in order to add the output signals.

The present invention relates to a position sensor, and to a method for operation of a position sensor.

One important field of use for position sensors relates to the field of automatic transmissions in motor vehicles. The aim here is to determine a respective driving mode, park, reverse, neutral, drive or P, R, N, D and additional driving modes 2, 3, 4 as a position by means of a position sensor, which in this case is also referred to as a selection range sensor.

Position sensors which can be evaluated electrically, for example based on Hall elements, are used for this purpose as position sensors which are largely free of wear. In one known apparatus, a row of Hall elements are provided, arranged linearly, in order to form a position sensor, over which a carriage is moved, without touching them. The carriage is fitted with a strip of permanent magnets for each Hall sensor in the movement direction, with these strips being bit-coded. Each Hall element therefore makes contact with the magnetic field of a permanent magnet in every possible position of the carriage, thus resulting in a measurement signal of greater or lesser strength in each case. The instantaneous position of the carriage is deduced by evaluation electronics on the basis of this measurement signal from each of the Hall elements. Furthermore, these signals are decoded discretely in the evaluation electronics, that is to say independently of the processor, in order to allow early clearance for starting the engine. The unambiguous positions P and N are used as a releasing bit pattern. Any other position prevents the vehicle engine from being started.

As so-called selection range switches, sensors such as these are also designed for operation within a machine, that is to say for use within a transmission. Output signals from the position sensors are evaluated by the electronic circuit to which the position sensors must be electrically connected. A connection such as this is implemented in various forms by means of a flexible sheet, a stamped grid, or else a cable loom. One object of the present invention is to improve the connection between position sensors and the respective evaluation electronics.

This object is achieved by the independent claims. According to the invention, in a method for operation of a position sensor having at least two Hall elements over which a carriage passes without touching them, with the carriage having a strip of permanent magnets for each Hall sensor in the movement direction and with the strips being bit-coded, the invention in this case provides for the output signals from in each case two Hall elements to be combined. A secondary signal is therefore formed from two primary signals and is then evaluated to determine the position. In this case, these two Hall elements or cells are preferably directly adjacent to one another. Thus, while according to the prior art, the state signal of each Hall cell has been transmitted in an analogously static form, a new secondary signal comprising two output signals with adjacent Hall elements is now formed according to the invention by combining two primary signals. This reduction of signal lines represents an improvement because connections between a position sensor and associated evaluation electronics are now less complex. Flexible sheets, stamped grids or else cable looms, or else in any case plug connections, can thus be produced more reliably and with less complexity.

Particularly against the background that an arrangement of evaluation electronics in the high-temperature and aggressive environment of a transmission is costly and complex, evaluation electronics are increasingly once again being arranged outside a transmission. In these cases, the width of a data bus or of a supply and measurement line is of major importance for the price and the reliability of a position sensor.

In one advantageous development of the invention, the voltage bands are restructured as follows: four bands reflect the four possible binary switching states of the two Hall elements. These four voltage bands are separated from one another by three intermediate bands or logically undefined areas. The two bands for a respective short-circuit situation are also located at the upper and lower ends of this voltage scale. In contrast, according to the prior art, each output signal which can be diagnosed completely from a Hall element has five mutually adjacent voltage bands: two voltage bands correspond to the permissible data signals. There is a logically undefined area between these two bands. The so-called short-circuit ranges with a conductive connection to the supply voltage and to ground are respectively located at the upper and lower ends of the voltage scale. The short-circuit range and the undefined area reflect all possible fault situations according to the prior art. The complexity according to the invention is therefore considerably less than that of apparatuses and methods according to the prior art.

The strips of permanent magnets are preferably formed on the slide, opposite adjacent strips, based on Gray coding. Any position change is therefore indicated by just one bit change. Any position change can therefore be identified and detected without any doubt. In one development of the invention, the strips (7) of permanent magnets (8) are arranged on the slide (6) opposite adjacent strips (7) such that any position change is indicated by just two bit changes.

In one preferred embodiment of the invention, the resultant secondary signal is then binary-coded via a resistance network, adjacent to the Hall elements. This resistance network is designed such that all the diagnosis voltage bands are also detected in conjunction with downstream evaluation electronics. Since only two signals are now transmitted instead of four, this reduces the circuit complexity both on the sensor mount and in the evaluation electronics. According to the prior art, each signal output of a pure primary signal requires two resistors in order to allow the voltage bands to be represented. The combination of primary signals in pairs to form one secondary signal in each case avoids the need for a resistor for each pair of Hall cells. At the receiving end and at the evaluation electronics end, only half as many input signals need be protected, filtered and recorded. This makes it possible to save two capacitors and one resistor for each Hall cell pair in a circuit. Furthermore, one analog measurement input becomes free for each Hall cell pair within the evaluation electronics at the processor end.

Furthermore, directly discrete decoding is possible despite the primary signals being combined to form in each case one secondary signal. This results in simple engine starting clearance. One precondition for this is a suitable sequence of Hall cells or Hall elements, that is to say a combination of the primary signals in such a way that the voltage bands for the P and N positions are closely adjacent to one another. This means that only two signals need be compared with the P and N patterns, instead of 4 as in the past.

A sensor arrangement according to the invention is advantageously connected via a voltage-limiting and/or voltage-regulating circuit element to a voltage supply for the actuators for the transmission.

A supply voltage which is provided in any case and is passed to the transmission can therefore be used at the same time to supply the Hall elements, by. means of a zener diode, a varistor, a voltage regulator, a voltage divider or the like. In contrast, according to the prior art, a separate line is in each case required for the supply voltage for the Hall sensors. A respective output in order to transmit measurement signals to evaluation electronics can be designed to be resistant to short circuits and protected against polarity reversal. In this case, according to the prior art itself, actuators are also generally located within a sensor mount, with a positive, unregulated supply voltage already being provided for the actuators in the transmission, although this is generally considerably above the sensor supply voltage level. According to the present embodiment of the invention, the integration means that there is no need for resistance to short circuits, or for polarity-reversal protection for the sensor supply.

Furthermore, there is no need for the additional buffering of the sensor supply required according to the prior art. Furthermore, from the circuitry point of view, there is only a short distance between the evaluation electronics as an energy source and the sensor mount with the Hall elements. This makes it possible to save a capacitor.

The number of connections to the position sensor is reduced by a combination, as carried out in pairs in this case, of a plurality of primary signals as output signals from the Hall elements of the position sensor, via a resistance network. In addition, the reliability of the interface connection is increased since, overall, this saves interfaces. Plug connectors with a reduced number of poles can now be used for transmission of sensor output signals after the signal preprocessing, as described above, to evaluation electronics which are located outside the transmission. In addition to improving the reliability of such electrical connections, this also results in potential cost reductions.

Furthermore, the input voltage range of the position sensor is increased by the use of sensor-internal voltage limiting. This reduces the circuit complexity of the sensor voltage supply, with one connection or pole in the area of the interface or of the plug also being saved.

Further features and advantages of embodiments according to the invention will be explained in more detail in the following text with reference to one exemplary embodiment and using the figures of the drawing, in which:

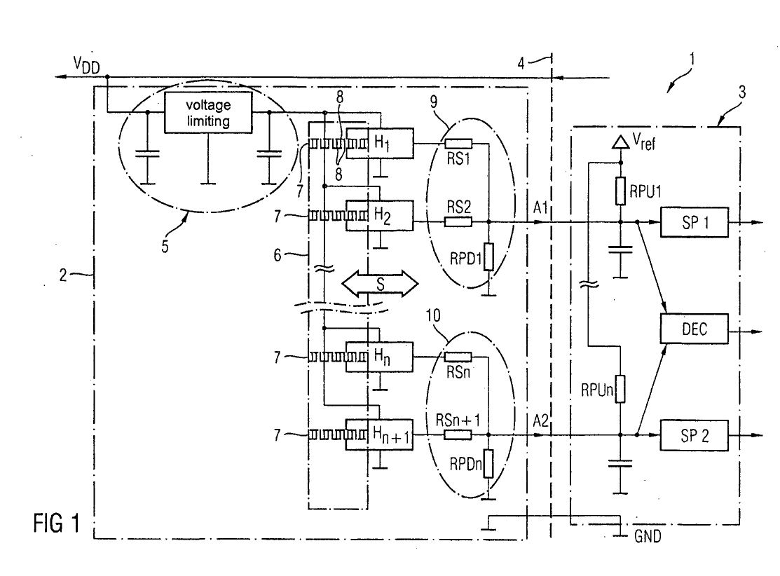

FIG. 1: shows a schematic illustration of an electrical circuit of a position sensor having Hall elements and evaluation electronics connected thereto, and

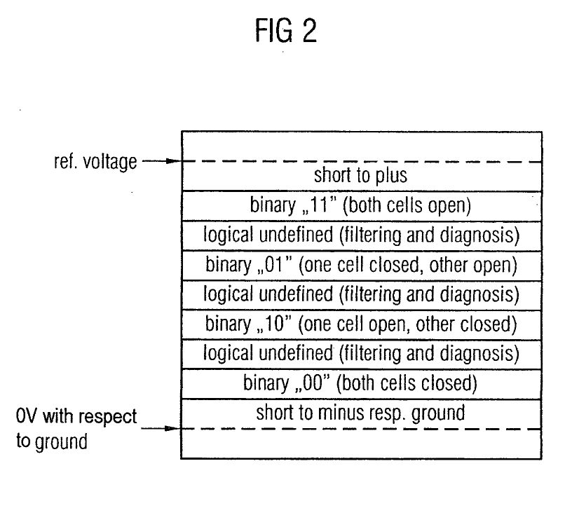

FIG. 2: shows a graph to illustrate the structure of the voltage bands used for static, analog signal transmission.

FIG. 1 shows a schematic illustration of an electrical circuit 1 comprising a position sensor 2 with evaluation electronics 3, connected via an interface 4. The interface 4 furthermore produces an electrical connection from the position sensor 2 to an actuator voltage supply V_{DD} and to a common reference ground potential GND.

In the present exemplary embodiment, the position sensor 2 comprises Hall elements H₁, H₂, Hₙ, Hₙ₊₁. The Hall elements H₁, H₂, Hₙ, Hₙ₊₁ are connected via a voltage-limiting or voltage-regulating circuit element 5 to the actuator voltage supply V_{DD}, so that there is no need for an additional contact, as was provided for this purpose in known apparatuses, in the area of the interface 4.

A moving carriage 6 makes contact with the row of Hall elements H₁, H₂, Hₙ, Hₙ₊₁, without touching them, via magnetic fields, with the carriage 6 being provided with a strip 7 of bit-coded permanent magnets 8 for each Hall sensor in the movement direction S. The strips 7 of permanent magnets 8 are designed and arranged on the carriage or slide 6 opposite respectively adjacent strips 7, using Gray coding. This means that any position change of the carriage 6 will be indicated by just one bit change via the Hall elements H₁, H₂, Hₙ, Hₙ₊₁.

In the present exemplary embodiment, each strip 7 comprises a total of 16 permanent magnets 8 in order to represent the states which occur in a modern automatic transmission. A specific output signal is produced via the magnetic field in a respective Hall element depending on the switch position or position of a strip 7 on the carriage 6 over the associated Hall elements H₁, H₂, Hₙ, Hₙ₊₁.

Signal outputs from in each case two Hall elements are combined for addition of the respective primary output signals in order to form just one secondary signal, with the Hall elements each being arranged directly adjacent to one another. The output signals from the pair of Hall elements H₁, H₂ are combined in a corresponding manner to form one secondary signal A1, and the output signals from the pair of Hall elements Hₙ, Hₙ₊₁ are combined to form the secondary signal A2. A resistance network 9, 10 in each case comprising two series resistors RSi and a parallel-connected resistor RPDi is then respectively provided for this purpose adjacent to these pairs of Hall elements H₁, H₂ and Hₙ, Hₙ₊₁, for binary coding of the resultant secondary signal A1, A2.

The secondary signals A1, A2 are then transmitted via the interface 4 to the evaluation electronics 3. For each of the incoming secondary signals A1, A2, the evaluation electronics 3 have a respective signal processor SP1, SP2, which is connected to a reference voltage V_{ref} via an RC network. Binary result values are then produced at the output of the signal processors SP1, SP2. The table in FIG. 2 shows the structure of the voltage bands that are used.

In addition, the secondary signals A1, A2 are additionally processed in parallel in a decoding unit DEC in the evaluation electronics 3, with this resulting in a processor-independent clearance to start the engine. This clearance to start the vehicle engine is produced when the evaluation electronics 3 identify an N position or P position via the selection range sensor.

The index n in the illustration in FIG. 1 indicates that this arrangement can in each case be extended by even-numbered multiples. The combination in pairs leads to binary results while, for example, a combination of three Hall elements could be processed using tristate logic or three-state logic.

1.-13. (canceled)

14. A method for operating a position sensor in which a carrier is moved over a series of Hall elements, without touching them, the carriage having a magnet strip comprising a bit-coded permanent magnet for each of the Hall elements extending in the movement direction of the carrier, the method comprising:
combining the output signal from each of a pair of Hall elements to form a secondary signal; and
determining the instantaneous position of the carriage by evaluation electronics based on the secondary signal.

15. The method of claim 14, wherein four voltage bands correspond to four possible binary switching states of the pair of Hall elements which are combined by circuitry, the bands are separated by respective intermediate bands or undefined areas.

16. The method of claim 14, wherein two of the magnetic strips corresponding to the pair of Hall elements are neighboring magnetic strips on the carriage and are disposed on the carriage based on Gray coding.

17. The method of claim 15, wherein the output signals of the pair of Hall elements corresponds to a two-bit binary signal, and wherein two of the magnetic strips corresponding to the pair of Hall elements are neighboring magnetic strips and are disposed on the carriage so that any position change is indicated by an equal change in the two-bit binary signal.

18. The method of claim 14, wherein the coding of the secondary signal is produced by a resistance network.

19. The method of claim 14, further comprising the step of supplying, by a voltage-limiting or voltage-regulating circuit element, electric power to the Hall elements.

20. The method of claim 14, wherein the position sensor is a selection range sensor in an automatic transmission of a motor vehicle.

21. The method of claim 14, wherein said step of combining comprises pairing off the Hall elements into pairs and combining the output signals of each pair of Hall elements to form respective secondary signals, wherein the instantaneous position of the carriage is determined using only the secondary signals.

22. A position sensor, comprising:
a series of Hall elements;
a moving carriage having magnetic strips respectively corresponding to said Hall elements, each of the magnetic strips including bit-coded permanent magnets, the moving carriage being disposed such that the moving carriage makes magnetic contact with the Hall elements without touching the Hall elements; and
evaluation electronics connected to the Hall elements, wherein output signals of two of the Hall elements are combined to form a secondary signal, the evaluation electronics being designed to determine an instantaneous position of the carriage based on the secondary signal.

23. The position sensor of claim 22, wherein the two Hall elements are arranged directly adjacent to one another.

24. The position sensor of claim 22, wherein four voltage bands correspond to the four possible binary switching states of the two Hall elements, the four voltage bands being separated by three intermediate bands or logically undefined areas, and two bands for a short-circuit situation being located at the upper and lower ends of this voltage scale, the evaluation electronics determining the instantaneous position by comparing the secondary signal to the voltage bands.

25. The position sensor of claim 22, wherein the magnetic strips corresponding to the two Hall elements are neighboring magnetic strips on a slide of the carriage and are arranged based on Gray coding.

26. The position sensor of claim 22, further comprising a resistance network for coding of the resultant secondary signal arranged adjacent to the Hall elements.

27. The position sensor of claim 22, further comprising a voltage-limiting or voltage-regulating circuit element connecting the Hall elements to a supply voltage, the circuit element comprising one of a zener diode, a varistor, a voltage regulator, or a voltage divider.

28. The position sensor of claim 22, wherein the Hall elements are connected to the evaluation electronics through an interface.

29. The position sensor of claim 22, wherein the position sensor is a selection range sensor in an automatic transmission of a motor vehicle.

30. The position sensor of claim 22, wherein the Hall elements are paired off into pairs and the output signals of each pair of Hall elements are combined to form respective secondary signals, such that the evaluation electronics determines the instantaneous position of the carriage using only the secondary signals.
